(19) United States
(12) Patent Application Publication
(10) Pub. No.: US 2022/0406881 A1
(43) Pub. Date: Dec. 22, 2022

(54) DISPLAY PANEL AND DISPLAY APPARATUS

(71) Applicant: WUHAN TIANMA MICROELECTRONICS CO., LTD., Wuhan (CN)

(72) Inventors: Lei Wang, Wuhan (CN); Yangzhao Ma, Wuhan (CN)

(73) Assignee: WUHAN TIANMA MICROELECTRONICS CO., LTD., Wuhan (CN)

(21) Appl. No.: 17/821,877

(22) Filed: Aug. 24, 2022

(30) Foreign Application Priority Data
Jun. 23, 2022 (CN) 202210718089.X

(51) Int. Cl. H01L 27/32; H01L 51/52

(52) U.S. Cl. CPC H01L 27/3279; H01L 27/3246; H01L 51/5284

(57) ABSTRACT

A display panel and a display apparatus are provided. The display panel comprises a display area, and a non-display area, data lines and connecting lines that are located in display area, pads, a substrate, and a light-shielding structure located in the display area and located at a side of the connecting line away from the substrate. The data line extends in a first direction, and the connecting line includes one end coupled with the data line and another end coupled with the pad. The data lines and the connecting lines are located at a same side of the substrate. In a direction perpendicular to a plane of the substrate, the light-shielding structure overlaps with at least one of line segments of the connecting line.

### CROSS-REFERENCE TO RELATED APPLICATIONS

The present application claims priority to Chinese Patent Application No. 202210718089.X, filed on Jun. 23, 2022, the content of which is incorporated herein by reference in its entirety.

### TECHNICAL FIELD

The disclosure relates to a technical field of displaying, in particular to a display panel and a display apparatus.

### BACKGROUND

In the related art, a lower frame of a display panel is provided with a fan-out line, and the fan-out line has one end connected to a display driving chip and another end connected to a data line located in a display area. However, the fan-out line occupies a large space of the lower frame, which leads to a large width of the lower frame and affects appearance. A design scheme in the related art is to dispose some of the fan-out lines in the display area to reduce the width of the lower frame. However, after some of the fan-out lines are disposed in the display area, the fan-out lines in the display area reflect a portion of ambient light. This results in a difference between the reflectivity of the display area with the fan-out lines provided therein to the ambient light and the reflectivity of other display areas with no fan-out lines provided therein to the ambient light, and thus a problem of picture non-uniformity in an off-screen state.

### SUMMARY

In a first aspect, some embodiments of the present disclosure provide a display panel, which has a display area and a non-display area. The display panel includes data lines arranged in the display area and each extending in a first direction, connecting lines arranged in the display area, pads arranged in the non-display area, a substrate, and a light-shielding structure located in the display area and located at a side of the connecting lines away from the substrate. Each of the connecting lines includes one end coupled with one of the data lines, and another end coupled with one of the pads. The data lines and the connecting lines are located at a same side of the substrate. In a direction perpendicular to a plane of the substrate, the light-shielding structure overlaps.

In a second aspect, based on a same inventive concept, a display apparatus is provided in some embodiments of the present disclosure, and includes the display panel. The display panel has a display area and a non-display area. The display panel includes data lines arranged in the display area and each extending in a first direction, connecting lines arranged in the display area, pads arranged in the non-display area, a substrate, and a light-shielding structure located in the display area and located at a side of the connecting lines away from the substrate. Each of the connecting lines includes one end coupled with one of the data lines, and another end coupled with one of the pads. The data lines and the connecting lines are located at a same side of the substrate. In a direction perpendicular to a plane of the substrate, the light-shielding structure overlaps.

### BRIEF DESCRIPTION OF DRAWINGS

In order to explain technical solutions in embodiments of the present disclosure or in the related art more clearly, the drawings used in the embodiments and in the related art will be briefly introduced below. The drawings in the following description illustrate some of the embodiments of the present disclosure, and other drawings can be obtained for those of skilled in the art according to these drawings.

FIG. 1 is a partial schematic diagram of a display panel according to some embodiments of the present disclosure;

FIG. 2 is a schematic cross-sectional view along line A-A′ shown in FIG. 1, according to some embodiments of the present disclosure;

FIG. 3 is another partial schematic diagram of a display panel according to some embodiments of the present disclosure;

FIG. 4 is a schematic cross-sectional view along line B-B′ shown in FIG. 3, according to some embodiments of the present disclosure;

FIG. 5 is another schematic diagram of a display panel according to some embodiments of the present disclosure;

FIG. 6 is another partial schematic diagram of a display panel according to some embodiments of the present disclosure;

FIG. 7 is another partial schematic diagram of a display panel according to some embodiments of the present disclosure;

FIG. 8 is another partial schematic diagram of a display panel according to some embodiments of the present disclosure;

FIG. 9 is another partial schematic diagram of a display panel according to some embodiments of the present disclosure;

FIG. 10 is another partial schematic diagram of a display panel according to some embodiments of the present disclosure;

FIG. 11 is another partial schematic diagram of a display panel according to some embodiments of the present disclosure;

FIG. 12 is a schematic cross-sectional view along line C-C′ shown in FIG. 11, according to some embodiments of the present disclosure;

FIG. 13 is another partial schematic diagram of a display panel according to some embodiments of the present disclosure;

FIG. 14 is another schematic diagram of a display panel according to some embodiments of the present disclosure;

FIG. 15 is another schematic diagram of a display panel according to some embodiments of the present disclosure;

FIG. 16 is another schematic diagram of a display panel according to some embodiments of the present disclosure;

FIG. 17 is another schematic diagram of a display panel according to some embodiments of the present disclosure; and

FIG. 18 is a schematic diagram of a display apparatus according to some embodiments of the present disclosure.

### DESCRIPTION OF EMBODIMENTS

In order to make purposes, technical schemes, and advantages of embodiments of the present disclosure clearer, technical schemes in the embodiments of the present disclosure will be clearly and completely described below with reference to the drawings in the embodiments of the present disclosure. The described embodiments are only some of the embodiments of the present disclosure, but not all of them. On a basis of the embodiments in this disclosure, all other embodiments obtained by those skilled in the art are within a protection scope of this disclosure.

Terms used in the embodiments of the present disclosure are only for the purpose of describing specific embodiments, but not intended to limit the present disclosure. Singular forms of “a”, “said”, and “the” used in the embodiments of the present disclosure and the appended claims are also intended to include a plural form, unless the context clearly indicates other meaning otherwise.

Fan-out lines are provided in a non-display area of a conventional display panel, and the fan-out lines are connecting lines connecting data lines in the display area and the driving chip in the non-display area. Because a distance between data lines in the display area is greater than a distance between adjacent pins on the driver chip, and in order to realize connection between the data lines in the display area and the pins of the driver chip, fan-out lines are provided in the non-display area, and distances between fan-out lines are gradually decreased in a direction from the display area to the driver chip. That is to say, multiple fan-out lines are led out from a boundary between the display area and the non-display area, and then gradually aggregated and converged, and then connected to respective pads, in which a predetermined space is occupied by the fan-out lines when they are aggregating and converging. In order to reduce a space occupied by the fan-out lines in the non-display area, some of the fan-out lines are disposed in the display area in the related art. However, the fan-out lines in the display area are reflective to the ambient light, which results in a difference between the reflectivity of the display area with the fan-out lines provided therein to the ambient light and the reflectivity of other display areas without fan-out lines provided therein to the ambient light, and thus a problem of picture non-uniformity in an off-screen state.

In order to solve problems in the related art, a display panel is provided in some embodiments of the present disclosure, in which a light-shielding structure is provided in a display area, so that at least some of the connecting lines are shielded by the light-shielding structure to reduce reflection of the connecting lines to the ambient light, thereby improving a problem of display non-uniformity in the off-screen state.

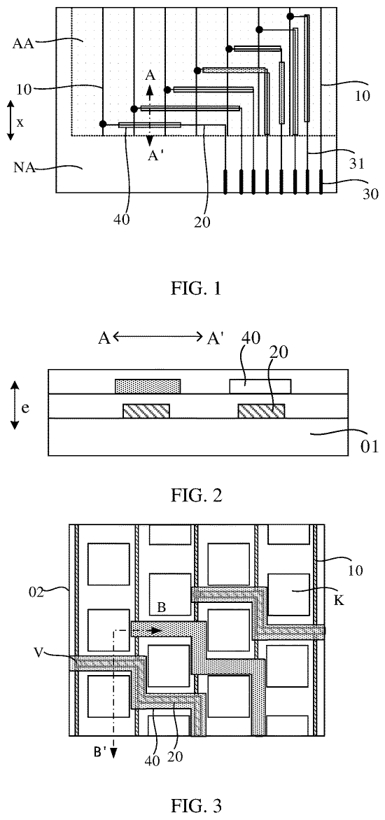

FIG. 1 is a partial schematic diagram of a display panel according to some embodiments of the present disclosure, and FIG. 2 is a schematic cross-sectional view along line A-A′ shown in FIG. 1. As shown in FIG. 1, the display panel includes a display area AA and a non-display area NA. The display panel includes data lines 10 and connecting lines 20 in the display area AA. The display panel includes pads 30 in the non-display area NA. The pad 30 is configured to be bound to a driving structure. The driving structure can be a driving chip or a flexible printed circuit board with the driving chip fixed thereto. The data line 10 extend in a first direction x, the connecting line 20 has an end coupled with the data line 10, and another end coupled with the pad 30. The display panel includes a light-shielding structure 40 located in the display area AA. As can be seen from FIG. 1, with the display panel also includes a lead 31 in the non-display area NA, and the data line 10 is directly connected to the pad 30 through the lead 31, while the connecting line 20 is also connected to the pad 30 through the lead 31. That is, as shown in FIG. 1, some of the data lines 10 in the display area AA are connected to the pads 30 through the connecting lines 20. In some embodiments, some of the data lines 10 in the display area AA are directly connected to the pads 30 through the leads 31.

As shown in FIG. 2, the display panel includes a substrate 01, and the data lines 10 and the connecting lines 20 are located at a same side of the substrate 01. The light-shielding structure 40 is located at a side of the connecting line 20 away from the substrate 01. In a direction e perpendicular to a plane of the substrate 01, the light-shielding structure 40 overlaps at least one of line segments of the connecting line 20.

A shape of the connecting line 20 in FIG. 1 is only shown schematically, only to illustrate a connection relationship between the connecting line 20 and the data line 10 and an overlapping relationship between the connecting line 20 and the light-shielding structure 40.

In the display panel according to the embodiments of the present disclosure, the connecting line 20 is arranged in the display area AA, at least one data line 10 is coupled with respective pad 30 through the connecting line 20, which is equivalent to that some fan-out lines which are originally arranged in the non-display area NA are now disposed in the display area AA in the present disclosure, so that a wiring space in the non-display area NA can be saved, thereby narrowing the non-display area NA. The light-shielding structure 40 is arranged at the side of the connecting line 20 away from the substrate 01, and at least one line segment of the line segments of the connecting line 20 is shielded by the light-shielding structure 40 to prevent the at least one line segment from reflecting ambient light, so that the reflection of the connecting lines 20 to the ambient light can be reduced, and the difference between reflectivity of the display area with the connecting lines 20 provided therein to the ambient light and reflectivity of the display area with no connecting lines 20 provided therein to the ambient light can be reduced, thereby improving picture non-uniformity in an off-screen state.

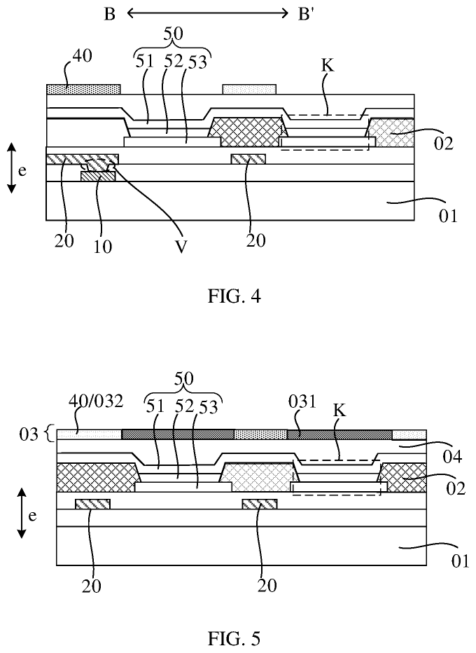

FIG. 3 is another partial schematic diagram of a display panel according to some embodiments of the present disclosure. FIG. 4 is another schematic cross-sectional view along line B-B′ shown in FIG. 3. FIG. 3 illustrates a partial top view of the display area AA. In some embodiments, as shown in FIG. 3, the display panel includes a pixel definition layer 02, and the pixel definition layer 02 has openings K located in the display area AA. One light-emitting element in the display area AA corresponds to one opening K. FIG. 3 is a top view of the display panel. It can be understood that the top view direction is parallel to the direction perpendicular to the plane of the substrate 01. It can be seen from FIG. 3 and FIG. 4 that, in the direction e perpendicular to the plane of the substrate 01, at least one of the line segments of the connecting line 20 does not overlap with the opening K, and the light-shielding structure 40 does not overlap with the opening K. The light-emitting element 50 is an organic light-emitting element or an inorganic light-emitting element. As can be seen from FIG. 4, the connecting line 20 and the data line 10 are located in different layers, and the connecting line 20 and the data line 10 are connected to each other through a via V passing through the insulating layer. FIG. 4 also illustrates a light-emitting element 50, and the light-emitting element 50 includes a first electrode 51, a light-emitting layer 52, and a second electrode 53. The opening K exposes the first electrode 51, the first electrode 51 is a reflective electrode, and the second electrode 53 is a transmissive electrode. The opening K is located in a light emitting area of the light-emitting element 50. As shown in FIG. 4, the connecting line 20 is located at a side of the first electrode 51 close to the substrate 01.

In some embodiments of the present disclosure, the connecting line 20 is located at a side of the light-emitting element 50 close to the substrate 01, and the connecting line 20 is located at a side of the data line 10 away from the substrate 01. When the connecting line 20 overlaps with the first electrode 51 in the direction perpendicular to the plane of the substrate 01, unevenness of the first electrode 51 occurs at this overlapping position, so that the pixel emits light unevenly in circumferential directions, resulting in a problem of display color cast. According to the embodiments of the disclosure, at least one of the line segments of the connecting line 20 are provided not to overlap with the opening K in the direction e perpendicular to the plane of the substrate 01, so at least one of the line segments of the connecting line 20 is disposed between adjacent openings K, and the at least one of the line segments of the connecting line 20 does not overlap with the first electrode 51. In this way, the problem of display color cast caused by uneven light emission from at least one of the light-emitting elements 50 in the circumferential directions can be improved, thereby improving the display performance. The light-shielding structure 40 does not overlap with the opening K in the direction e perpendicular to the plane of the substrate 01, and providing the light-shielding structure 40 does not affect light emission of the light-emitting element 50, thereby ensuring light emitting efficiency of the light-emitting element 50. Meanwhile, the light-shielding structure 40 is configured to shield at least one connecting line 20 of the connecting lines 20 between adjacent openings K, so as to prevent the at least one connecting line 20 from reflecting light, and thus to improve the problem of picture non-uniformity in the off-screen state.

In some embodiments, the connecting line 20 is a broken line including multiple line segments, and the connecting line 20 is wired in the display area AA from a boundary between the display area AA and the non-display area NA. The connecting line 20 does not overlap with the opening K, that is, each line segment of the connecting line 20 are wired between the adjacent openings K, which can minimize effect on circumferential light emission of the light-emitting element 50 and avoid the problem of display color cast.

In some embodiments, the light-shielding structure 40 is located at a side of the light-emitting element 50 away from the substrate 01. FIG. 5 is another schematic diagram of a display panel according to some embodiments of the present disclosure. As shown in FIG. 5, the display panel includes a filter layer 03, the filter layer 03 includes multiple filter units 031, and a light-shielding component 032 is provided between adjacent filter units 031. The light-shielding structure 40 is reused as the light-shielding component 032. In some embodiments, the filter unit 031 includes a red filter unit, a blue filter unit, and a green filter unit. In some embodiment, the display panel includes an encapsulation layer 04. The encapsulation layer 04 is located at a side of the light-emitting element 50 away from the substrate 01 and is configured to isolate water and oxygen so as to ensure service life of the light-emitting element 50. The filter layer 03 is located at a side of the encapsulation layer 04 away from the light-emitting element 50. In some embodiments, the light-emitting element 50 includes a red light-emitting element, a green light-emitting element, and a blue light-emitting element. In the direction perpendicular to the plane of the substrate 01, the red filter unit overlaps with the red light-emitting element, the blue filter unit overlaps with the blue light-emitting element, and the green filter unit overlaps with the green light-emitting element. In other embodiments, the light-emitting element 50 is a white light-emitting element, and the filter unit 031 overlaps with the white light-emitting element in the direction perpendicular to the plane of the substrate 01.

The filter unit 031 has filtering property, which only allows light with a specific color to pass through. For example, red light can pass through the red filter unit, while green light and blue light cannot pass through the red filter unit. When the ambient light radiates on the red filter unit, only red light can pass through the red filter unit to reach the light-emitting element 50 under the red filter unit, and then the red light reflected by the first electrode 51 of the light-emitting element 50 can only be emitted out from the red filter unit, and the red light with a large angle reflected by the first electrode 51 cannot be emitted out from surrounding green filters unit or blue filter units, so that a part of the light reflected by the first electrode 51 can be restricted in the panel and cannot be emitted out, thereby reducing reflectivity of the display panel to the ambient light and improving the display performance. In the embodiment of the disclosure, the light-shielding structure 40 is reused as the light-shielding component 032, which can save manufacturing processes. The light-shielding structure 40 can shield the connecting line 20 located below light-shielding structure 40, reduce reflection of the connecting line 20 to the ambient light, and improve the problem of picture non-uniformity in the off-screen state. Meanwhile, the light-shielding structure 40 is reused as the light-shielding component 032, which can separate adjacent filter units 031 and prevent crosstalk.

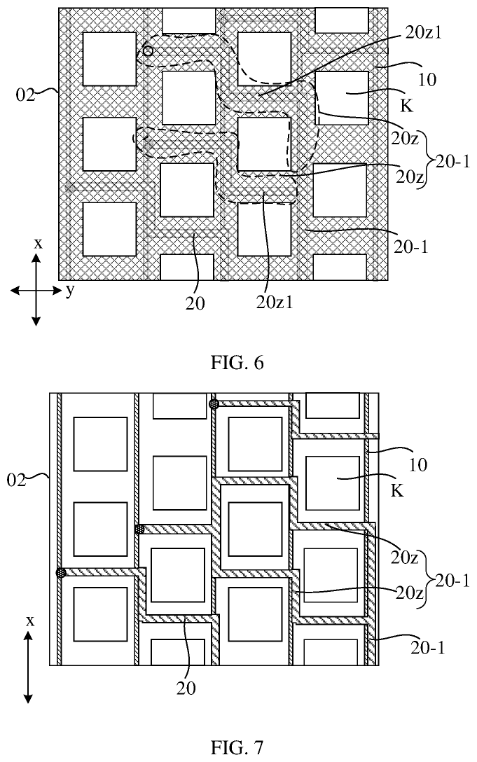

FIG. 6 is another partial schematic diagram of a display panel according to some embodiments of the present disclosure. In some embodiments, as shown in FIG. 6, the connecting line 20 includes a first connecting line 20-1, and the first connecting line 20-1 includes at least two branches 20z connected in parallel. For two branches 20z, connecting in parallel of the two branches 20z indicates that the two branches 20z are electrically connected at at least two different points. In the embodiments of the present disclosure, at least one of the data lines 10 is provided to be coupled with the pad 30 through the connecting line 20 in the display area AA, which is equivalent to that at least one of the fan-out lines which is originally arranged in the non-display area NA is now disposed in the display area AA in the present disclosure. A length of the connecting line 20 in the display area AA can be greater than a length of a conventional fan-out line, so that impedance of the connecting line 20 can be large, which results in a large load on the data line 10 coupled with the connecting line 20 and affects the charging and discharging time of the data line 10. In the embodiment of the present disclosure, the first connecting line 20-1 includes at least two branches 20z connected in parallel, which can reduce resistance of the first connecting line 20-1, thereby reducing the load on the data line 10 coupled with the first connecting line 20-1, and thus reducing the charging and discharging time of the data line 10 and improving a response speed.

In some embodiments, as shown in FIG. 6, all branches 20z of the first connecting line 20-1 are coupled with a same data line 10 at different positions of the same data line 10. According to this embodiment, all the branches 20z of the first connecting line 20-1 charge the data line 10 at the positions where they are coupled with the data line 10, and the data line 10 discharges electricity to all the branches 20z of the first connecting line 20-1 at these positions, which are more conducive to improving the charging and discharging speed of the data line 10.

FIG. 7 is another partial schematic diagram of a display panel according to the embodiment of the present disclosure. In other embodiments, as shown in FIG. 7, at least two of the branches 20z of the first connecting line 20-1 are coupled with a same data line 10 at a same position of the same data line 10. In FIG. 7, all of the branches 20z of the first connecting line 20-1 are coupled with the same data line 10 at the same position of the same data line 10. In the embodiments, at least two branches 20z connected in parallel can reduce the resistance of the first connecting line 20-1, reduce the load on the data line 10 coupled with the first connecting line 20-1, reduce the charging and discharging time of the data line 10, and improve the response speed. Meanwhile, at least two of the branches 20z of the first connecting line 20-1 are coupled with the same data line 10 at a same position of the same data line 10, which can reduce the number of holes in the insulating layer and facilitate saving of a wiring space in the display panel.

In some embodiments, all branches 20z of the connecting line 20 are provided in a same layer and made of a same material. That is, all branches 20z of the connecting line 20 are manufactured in a same process, which can simplify the process. Only one conductive layer can be added to the display panel to manufacture the connecting line 20, which has little effect on an overall thickness of the display panel.

In some embodiments, in a same display panel, all branches 20z of at least one of the first connecting lines 20-1 can be coupled with a same data line 10 at different positions of the data line 10, and at least two of the branches 20z of at least one remaining first connecting line 20-1 can be coupled with the same data line 10 at the same position of the same data line 10.

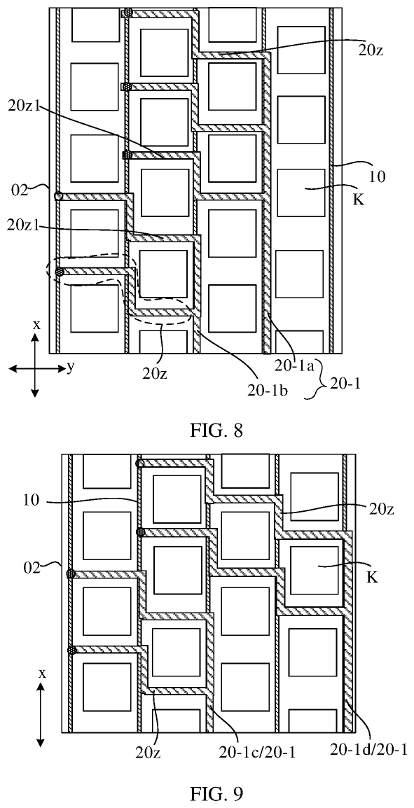

In some embodiments, the connecting line 20 includes multiple first connecting lines 20-1, and the numbers of the branches 20z of the first connecting lines 20-1 can be the same or different from each other. FIG. 8 is another partial schematic diagram of a display panel according to some embodiments of the present disclosure. As shown in FIG. 8, the first connecting line 20-1 includes a first connecting sub-line 20-1a and a second connecting sub-line 20-1b. The first connecting sub-line 20-1a includes three branches 20z connected in parallel, and the second connecting sub-line 20-1b includes two branches 20z connected in parallel, that is, a number of the branches 20z of the first connecting sub-line 20-1a is greater than a number of the branches 20z of the second connecting sub-line 20-1b. The more branches 20z included in the first connecting line 20-1, the more favorable it is to reduce the resistance of the first connecting line 20-1. In applications, the number of branches 20z of the first connecting sub-line 20-1a is different from the number of branches 20z of the second connecting sub-line 20-1b, so it is possible to balance impedance difference caused by different lengths of different first connecting lines 20-1 by setting different numbers of branches 20z included in the first connecting line 20-1. When impedance difference between the first connecting lines 20-1 with different lengths becomes smaller, load difference between the data lines 10 connected to different first connecting lines 20-1 can be reduced, so that difference of charging and discharging speeds of different data lines 10 is smaller, and uniformity of display brightness can be improved.

FIG. 9 is another partial schematic diagram of a display panel according to some embodiments of the present disclosure. In other embodiments, as shown in FIG. 9, the first connecting line 20-1 includes a third connecting sub-line 20-1c and a fourth connecting sub-line 20-1d, and the branch 20z of the third connecting sub-line 20-1c and the branch 20z of the fourth connecting sub-line 20-1d have different lengths. The longer the branch 20z of the first connecting line 20-1 is, the more favorable it is to reduce the resistance of the first connecting line 20-1. By adjusting the length of the branch 20z, the resistance of the first connecting line 20-1 can be adjusted. A length of the branch 20z of the third connecting sub-line 20-1c is different from a length of the branch 20z of the fourth connecting sub-line 20-1d, so it is possible to balance impedance difference caused by different lengths of the third connecting sub-line 20-1c and the fourth connecting sub-line 20-1d by setting different lengths of the branches 20z, and a difference between the load on the data lines 10 connected to different first connecting lines 20-1 can be reduced, so that a difference between charging and discharging speeds of different data lines 10 is smaller, thereby improving uniformity of display brightness.

FIG. 6 to FIG. 9 illustrate partial top views of the display area AA. In order to clearly illustrate a structure of the connecting line 20, the light-shielding structure 40 is not shown in FIG. 6 to FIG. 9, and the light-shielding structure 40 can be referred to the embodiments of FIG. 1 to FIG. 5. In the direction perpendicular to the plane of the substrate 01, the light-shielding structure 40 overlaps with at least one branch 20z of the line segments of the branches 20z, so that at least one branch 20z can be shielded by the light-shielding structure 40 to prevent the at least one branch 20z from reflecting the ambient light.

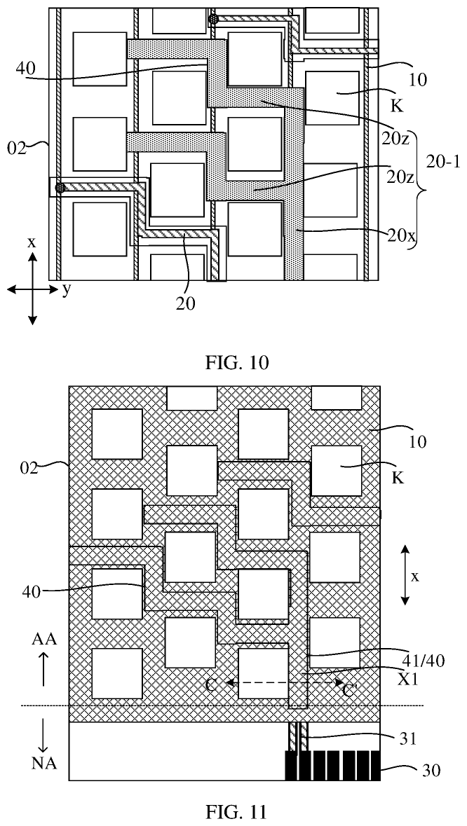

FIG. 10 is another partial schematic diagram of a display panel according to some embodiments of the present disclosure, and FIG. 10 illustrates the light-shielding structure 40 based on FIG. 6 described above. In some embodiments, as shown in FIG. 10, in the direction perpendicular to the plane of the substrate 01, the branch 20z does not overlap with the opening K, and the light-shielding structure 20 overlaps with the branch 20z. With the light-shielding structure 40 shielding the branch 20z, the branch 20z can be prevented from reflecting the ambient light, thereby reducing reflection of the connecting line 20 to the ambient light, reducing the difference between the reflectivity of the display area with the connecting lines 20 provided therein to the ambient light and the reflectivity of the display area with no the connecting lines 20 provided therein to the ambient light, and thus improving picture non-uniformity in the off-screen state.

As shown in FIG. 10, the branch 20z is wired between the adjacent openings K, and at least one of the line segments of only one branch 20z is provided between the adjacent openings K. That is, the branch 20z is wired between adjacent light-emitting elements, and only one branch 20z is provided between adjacent light-emitting elements. A width of the branch 20z can be made as large as possible between the adjacent openings K, which facilitates reducing of the resistance of the connecting line 20 as a whole. When the light-shielding structure 40 is arranged to shield the branch 20z, light emitting of the light-emitting element cannot be affected, and light emitting efficiency of the light-emitting element can be ensured.

As shown in FIG. 6, the branch 20z includes a first branch segment 20z1 extending in a second direction y, and the second direction y intersects with the first direction x. In a same first connecting line 20-1, one opening K is located in a space between two first branch segments 20z1 adjacent in the first direction x which respectively belong to two branches 20z. With such configuration, a distance between two adjacent branches 20z in a same first connecting line 20-1 can be reduced, which facilitates reducing of the overall length of the first connecting line 20-1 and the resistance of the first connecting line 20-1, thus reducing the load on the data line 10 coupled with the first connecting line 20-1, reducing the charging and discharging time of the data line 10, and improving the response speed.

As shown in FIG. 8, the branch 20z includes a first branch segment 20z1 extending in the second direction y, and one opening K is located in a space between two first branch segments 20z1 adjacent in the first direction which respectively belong to two adjacent first connecting lines 20-1. With such configuration, a distance between two adjacent first connecting lines 20-1 can be reduced, which facilitates reducing of difference between resistances of two first connecting lines 20-1, thus reducing load difference between different data lines 10.

In some embodiments, taking the embodiment of FIG. 10 as an example, the first connecting line 20-1 includes a main line segment 20x, and an end of each branch 20z is coupled with the main line segment 20x. In the direction perpendicular to the plane of the substrate 01, the main line segment 20x does not overlap with the opening K, and the main line segment 20x may not affect uniformity of light emitted from the light-emitting element in the circumferential directions, thus ensuring the display performance. The light-shielding structure 40 overlaps with at least a part of the main line segment 20x, which can prevent this at least the part of the main line segment 20x from reflecting light, thereby reducing reflection of the connecting line 20 to the light, reducing the difference between the reflectivity of the display area with the connecting lines 20 provided therein to the ambient light and the reflectivity of the display area with no connecting lines 20 provided therein to the ambient light, and improving picture non-uniformity in an off-screen state.

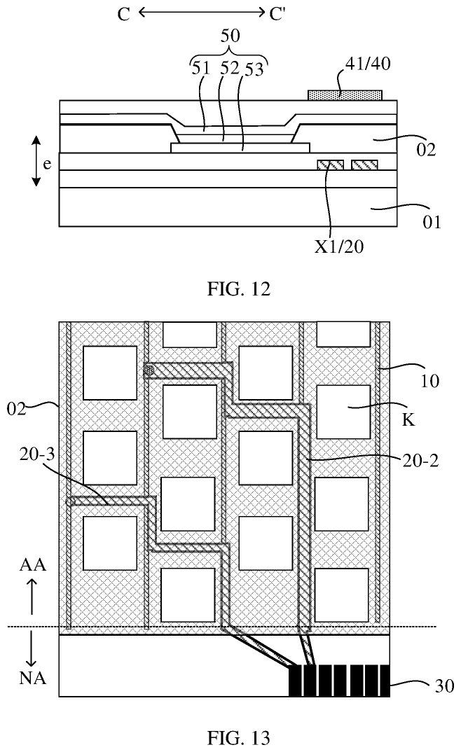

FIG. 11 is another schematic diagram of a display panel according to some embodiments of the present disclosure, and FIG. 12 is a schematic cross-sectional view along line C-C′ in FIG. 11. In some embodiments, as shown in FIG. 11, the connecting line 20 includes a first line segment X1 extending in the first direction x, and the first line segment X1 extends from a boundary between the display area AA and the non-display area NA to the display area AA. The light-shielding structure 40 includes a first light-shielding portion 41 extending in the first direction x. As shown in FIG. 12, in the direction e perpendicular to the plane of the substrate 01, the first light-shielding portion 41 overlaps with at least two first line segments X1. It can be seen from FIG. 11 that the pixel definition layer 02 extends from the display area AA to the non-display area NA, and the connecting line 20 is coupled with the pad 30 through the lead 31 located in the non-display area NA. In the embodiments, the first light-shielding portion 41 is arranged to overlap with at least two first line segments X1, so that it is possible to design the positions of the first line segments X1 according to a position of the pad 30, and it can be ensured that the first line segments X1 do not overlap with the opening K, thus avoiding a problem of display color cast of the light-emitting element 50 caused by overlapping between the first line segments X1 and the opening K. The first light-shielding part 41 shields the first line segment X1 to prevent the first line segment X1 from reflecting light, which can reduce the reflection of the connecting line 20 to the ambient light, reducing the difference between the reflectivity of the display area with the connecting lines 20 provided therein to the ambient light and the reflectivity of the display area with no connecting lines 20 provided therein to the ambient light, and improve picture non-uniformity in the off-screen state.

FIG. 13 is another partial schematic diagram of a display panel according to some embodiments of the present disclosure. In some embodiments, as shown in FIG. 13, the connecting lines 20 include a second connecting line 20-2 and a third connecting line 20-3, and a length of the second connecting line 20-2 is greater than a length of the third connecting line 20-3. A line width of at least one of the line segments of the second connecting line 20-2 is larger than a line width of the third connecting line 20-3. In the embodiments, with the line width of at least one of the line segments of the second connecting line 20-2 being increased, an overall resistance of the second connecting line 20-2 can be reduced, thus balancing resistance difference between the second connecting line 20-2 and the third connecting line 20-3 due to their different lengths, making the overall resistance difference between the second connecting line 20-2 and the third connecting line 20-3 small, thereby reducing load difference on data lines 10 respectively coupled with the second connection line 20-2 and the third connection line 20-3, making the charging and discharging time of the data lines 10 basically consistent, and improving display uniformity.

The light-shielding structure 40 is not shown in FIG. 3, and the light-shielding structure 40 can be understood with reference to related embodiments described above.

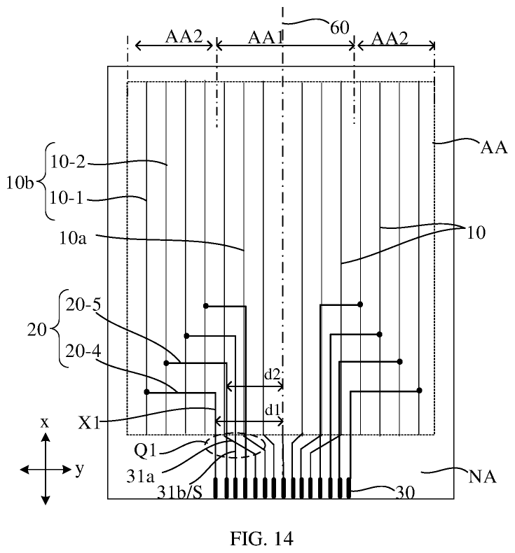

FIG. 14 is another schematic diagram of a display panel according to some embodiments of the present disclosure. In order to clearly illustrate a corresponding connection relationship between the connecting line 20 and the data line 10, the opening K of the pixel definition layer 02 and the light-emitting elements 50 in the display area AA are not illustrated in FIG. 14.

In some embodiments, as shown in FIG. 14, the display area AA has an axis of symmetry 60 extending in the first direction x. The connecting line 20 includes a first line segment X1 extending in the first direction x, and the first line segment X1 extends from a boundary between the display area AA and the non-display area NA to the display area AA. At a side of the axis of symmetry 60, the connecting lines 20 include a fourth connecting line 20-4 and a fifth connecting line 20-5, and the data lines 10 include a first data line 10-1 and a second data line 10-2. A distance d1 between the first line segment X1 of the fourth connecting line 20-4 and the axis of symmetry 60 is greater than a distance d2 between the first line segment X1 of the fifth connecting line 20-5 and the axis of symmetry 60. A distance between the first data line 10-1 and the axis of symmetry 60 is greater than the distance between the second data line 10-2 and the axis of symmetry 60. The fourth connecting line 20-4 is coupled with the first data line 10-1, and the fifth connecting line 20-5 is coupled with the second data line 10-2. Taking a left side of the axis of symmetry 60 in FIG. 14 as an example, in the embodiment of the present disclosure, it can be realized that the first pad 30 in the non-display area NA from left to right is coupled with the first data line 10 in the display area AA from left to right, and the second pad 30 in the non-display area NA from left to right is coupled with the second data line 10 in the display area AA from left to right, that is, the data lines 10 in the display area AA are sequentially connected to the pads 30 in the non-display area NA in one-to-one correspondence. With such configuration, positions of output pins of the driving chip do not need to be adjusted, and the display panel according to the embodiment of the disclosure can be applied to most of driving chips in the related art. With the sequential connection between the data line 10 and the pad 30 in FIG. 14, wirings of the connecting line 20 in the display area AA can be reduced, and the load on the data line 10 coupled with the connecting line 20 can be reduced. Meanwhile, the difference between lengths of adjacent connecting lines 20 can be reduced, the difference between loads on the data lines 10 coupled with the connecting lines 20 can be reduced, and the display uniformity can be improved.

In FIG. 14, the first line segment X1 of the connecting line 20 is illustrated to be approximately straight, and a line segment where the first line segment X1 is connected to the data line 10 is also approximately straight. A line shape of the connecting line 20 in FIG. 14 is only shown schematically. In some embodiments, at least one of the connecting lines 20 are broken lines shown in the embodiment of FIG. 3.

In some embodiments, as shown in FIG. 14, the display area AA includes a first display area AA1 and two second display areas AA2. In the second direction y, two second display areas AA2 are respectively located at two sides of the first display area AA1, and the second direction y intersects with the first direction x. The axis of symmetry 60 is located in the first display area AA1. The data lines 10 include intermediate data lines 10a and edge data lines 10b. The intermediate data lines 10a are located in the first display area AA1 and the edge data lines 10b are located in the second display area AA2. A fan-out line S is located in the non-display area NA, and the intermediate data line 10a is coupled with the pad 30 through the fan-out line S. The connecting line 20 is located in the second display area AA2, and the connecting line 20 is coupled with the edge data line 10b. The fan-out line S is the lead described in the embodiment of FIG. 1. It can be regarded that a first lead 31a and a second lead 31b are provided in the non-display area NA. The connecting line 20 is coupled with the pad 30 through the first lead 31a, and the intermediate data line 10a is coupled with the pad 30 through the second lead 31b, and the second lead 31b is the fan-out line S. As shown in a circled position Q1 in FIG. 14, at least one of the first leads 31a overlaps with the fan-out line S in the direction perpendicular to the plane of the substrate 01, and the first lead 31a and the fan-out line S can be arranged in different metal layers at least at a position where the first lead 31a overlaps with the fan-out line S, to prevent the short circuit between the first lead 31a and the fan-out line S. In the embodiment of the present disclosure, the fan-out lines originally to be provided in the non-display area NA are disposed in the display area AA in the present disclosure, and the connecting line 20 in the display area AA is configured to couple the data line 10 with the pad 30, so that widths occupied by the fan-out lines S in the second direction y can be reduced, thereby saving wiring space in the non-display area NA and facilitating narrowing of the non-display area NA. And at least one of the fan-out lines S is still remained in the non-display area NA, and the intermediate data line 10a is coupled with the pad 30 through the fan-out line S, which can reduce the number of the connecting lines 20 arranged in the display area AA, simplify the wiring mode in the display area AA, and also reduce reflection probability of the connecting lines 20 to the ambient light in the display area AA.

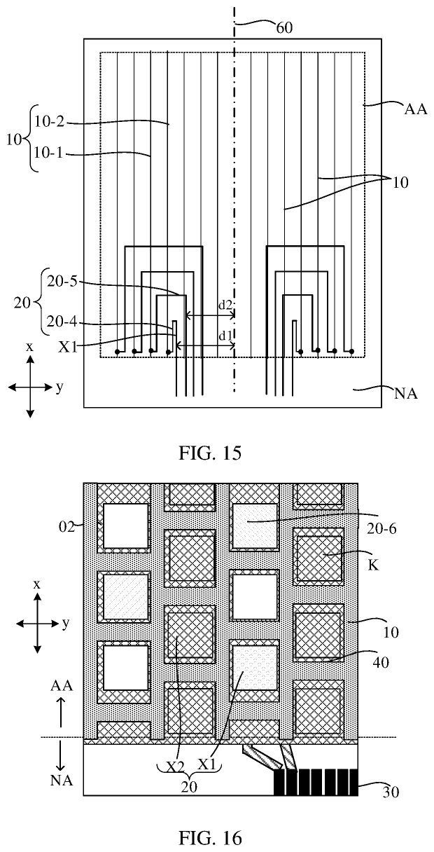

FIG. 15 is another schematic diagram of a display panel according to some embodiments of the present disclosure. In other embodiments, as shown in FIG. 15, the connecting line 20 includes a first line segment X1 extending in the first direction x, and the first line segment X1 extends from a boundary between the display area AA and the non-display area NA to the display area AA. At a side of the axis of symmetry 60, the connecting lines 20 include a fourth connecting line 20-4 and a fifth connecting line 20-5, and the data lines 10 include a first data line 10-1 and a second data line 10-2. A distance d1 between the first line segment X1 of the fourth connecting line 20-4 and the axis of symmetry 60 is greater than a distance d2 between the first line segment X1 of the fifth connecting line 20-5 and the axis of symmetry 60. A distance between the first data line 10-1 and the axis of symmetry 60 is greater than a distance between the second data line 10-2 and the axis of symmetry 60. The fourth connecting line 20-4 is coupled with the second data line 10-2, and the fifth connecting line 20-5 is coupled with the first data line 10-1. The first line segment X1 is an initial line segment of the connecting line 20 introduced from the boundary between the display area AA and the non-display area NA. In these embodiments, the farther the first line segment X1 in the connecting line 20 is from the axis of symmetry 60, the closer the data line 10 coupled with the connecting line 20 is from the axis of symmetry 60. With such configuration, the connecting lines 20 can be wired in the display area AA so that connecting lines 20 are all coupled with the data line 10 at positions close to the non-display area NA in the display area AA, and it is possible to realize that distances between the coupling points of the respective connecting lines 20 with the data line 10 and the non-display area NA in the first direction x is basically the same. The light-shielding structure 40 is not shown in FIG. 15. Referring to illustration of a positional relationship between the light-shielding structure 40 and the connecting line 20 in related embodiments described above, the light-shielding structure 40 is provided to overlap with at least one of the connecting lines 20 in the direction perpendicular to the plane of the substrate 01.

FIG. 16 is another schematic diagram of a display panel according to some embodiments of the present disclosure. In some embodiments, as shown in FIG. 16, the connecting lines 20 include a sixth connecting line 20-6. In the direction perpendicular to the plane of the substrate 01, at least one of line segments of the sixth connecting line 20-6 overlaps with the opening K. It can be seen from the related embodiments described above that the opening K exposes the first electrode 51 of the light-emitting element 50, and the first electrode 51 is a reflective electrode, so that at least one of the line segments of the sixth connecting line 20-6 overlapping with the opening K can be shield by the first electrode 51, and this at least one of the line segments does not reflect the ambient light. As shown schematically in FIG. 16, a part of the sixth connecting line 20-6 between the adjacent openings k overlaps with the light-shielding structure 40, and the light-shielding structure 40 is configured to shield at least one of the line segments of the sixth connecting line 20-6 between the adjacent openings k, so that reflection of the sixth connecting line 20-6 to the ambient light can be reduced. A line shape of the sixth connecting line 20-6 is only schematically illustrated, which does not limit the present disclosure.

In some embodiments, as shown in FIG. 16, the connecting line 20 includes a first line segment X1 extending in the first direction x, and the first line segment X1 extends from a boundary between the display area AA and the non-display area NA to the display area AA. The connecting lines 20 include a second line segment X2 extending in the second direction y, one end of the second line segment X2 is coupled with the first line segment X1, and another end of the second line segment X2 is coupled with the data line 10. In this embodiment, the first line segment X1 and the second line segment X2 are approximately straight lines, and it can be seen from FIG. 16 that, in the direction perpendicular to the plane of the substrate 01, at least one of the line segments of the first line segments X1 overlaps with the opening k, and at least one of line segments of the second line segment X2 overlaps with the opening K. It can be understood that the connecting line 20 overlapping with the opening K can be shield by the first electrode 51, and this at least one of the line segments will not reflect the ambient light. In some embodiments of the disclosure, in the direction perpendicular to the plane of the substrate 01, at least one of the line segments of the first line segment X1 overlaps with the light-shielding structure 40 while at least one of line segments of the second line segment X2 overlaps with the light-shielding structure 40. In this embodiment, the light-shielding structure 40 can be reused as the light-shielding component 032 in the filter layer 03. In some embodiments, the light-shielding structure 40 shields at least one of the line segments of the first line segment X1 that does not overlap with the opening K, while the light-shielding structure 40 shields at least one of the line segments of the second line segment X2 that does not overlap with the opening K, so as to ensure that the at least one of the line segments of the first line segment X1 that does not overlap with the opening K cannot reflect the ambient light, and the at least one of the line segments of the second line segment X2 that does not overlap with the opening K cannot reflect the ambient light. Therefore, reflection of the connecting line 20 to the ambient light can be reduced, the difference between the reflectivity of the display area with the connecting lines 20 provided therein to the ambient light and the reflectivity of the display area with no connecting lines 20 provided therein to the ambient light, and picture non-uniformity in the off-screen state can be improved.

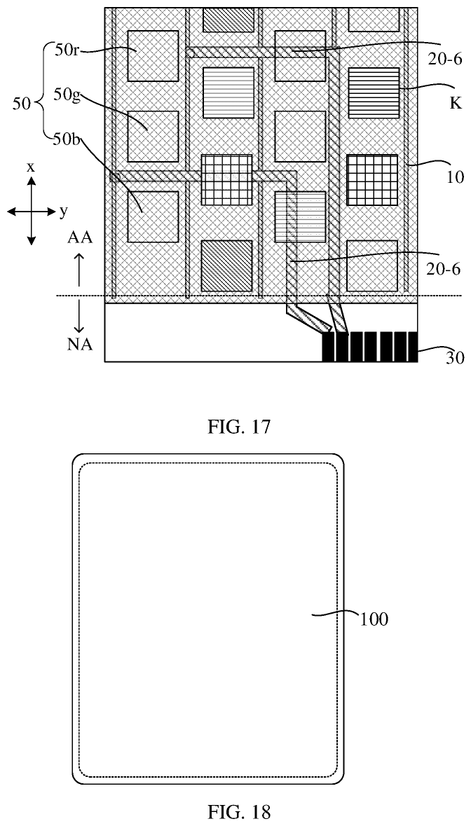

FIG. 17 is another schematic diagram of a display panel according to some embodiments of the present disclosure. In some embodiments, as shown in FIG. 17, light-emitting elements 50 are provided in the display area AA, and one light-emitting element 50 corresponds to one opening K. The light-emitting elements 50 include a red light-emitting element 50r, a green light-emitting element 50g, and a blue light-emitting element 50b. In the direction perpendicular to the plane of the substrate 01, at least one of the line segments of the sixth connecting line 20-6 overlaps with an opening K corresponding to the red light-emitting element 50r, and/or at least one of the line segments of the sixth connecting line 20-6 overlaps with an opening K corresponding to the blue light-emitting element 50b. That is, the at least one of the line segments of the sixth connecting line 20-6 overlaps with the red light-emitting element 50r, or the at least one of the line segments of the sixth connecting line 20-6 overlaps with the blue light-emitting element 50b. The sixth connecting line 20-6 does not overlap with the green light-emitting element 50g. An arrangement of the light-emitting elements 50 in FIG. 17 is only a schematic representation, which will not limit the present disclosure. The light-shielding structure 40 is not shown in FIG. 17. In this embodiment, it is not necessary to avoid the opening K corresponding to the red light-emitting element 50r and the opening K corresponding to the blue light-emitting element 50b in designing a wiring pattern of the sixth connecting line 20-6, so that the wiring pattern of the sixth connecting line 20-6 can be simplified. Meanwhile, the sixth connecting line 20-6 does not overlap with the green light-emitting element 50g, which can avoid effect of the arrangement of the sixth connecting line 20-6 on the uniform light emission of the green light-emitting element 50g in all directions, and also can reduce effect on the display color cast.

Based on a same concept, some embodiments of the present disclosure provide a display apparatus. FIG. 18 is a schematic diagram of a display apparatus according to some embodiments of the present disclosure. As shown in FIG. 18, the display apparatus includes the display panel 100 according to any embodiment of the present disclosure. The structure of the display panel 100 has been described in the above embodiments, which will not be repeated herein. The display apparatus according to some embodiments of the disclosure can be any device with a display function, such as a mobile phone, a tablet computer, a notebook computer, a television, or the like.

The above are only preferred embodiments of the present disclosure, but not intended to limit the present disclosure. Any modifications, equivalents, improvements, etc. made within the principle of the present disclosure fall within the scope of the present disclosure.

Finally, it should be noted that the above embodiments are only some of the embodiments to illustrate technical schemes of the present disclosure, but not to limit it. Although the present disclosure has been described in detail with reference to the foregoing embodiments, it should be understood by those skilled in the art that modifications can be made to the technical schemes described in the foregoing embodiments, or equivalent substitutions can be made to part or all of technical features thereof. These modifications or substitutions do not cause essence of corresponding technical schemes to depart from the scope of the technical schemes of the embodiments of the present disclosure.

What is claimed is:

1. A display panel, wherein the display panel has a display area and a non-display area; and
wherein the display panel comprises:
data lines arranged in the display area and each extending in a first direction;
connecting lines arranged in the display area;
pads arranged in the non-display area, wherein each of the connecting lines comprises an end coupled with one of the data lines, and another end coupled with one of the pads;
a substrate, wherein the data lines and the connecting lines are located at a same side of the substrate; and
a light-shielding structure located in the display area, and located at a side of the connecting lines away from the substrate, wherein, in a direction perpendicular to a plane of the substrate, the light-shielding structure overlaps with at least one of line segments of at least one of the connecting lines.

2. The display panel according to claim 1, further comprising:
a pixel definition layer comprising openings located in the display area, wherein, in the direction perpendicular to the plane of the substrate, the at least one of the line segments of the at least one of the connecting lines does not overlap with the openings, and the light-shielding structure does not overlap with the openings.

3. The display panel according to claim 1, wherein the connecting lines comprise at least one first connecting line, wherein each of the at least one first connecting line comprises at least two branches connected in parallel.

4. The display panel according to claim 3, wherein each of the at least two branches is coupled with different positions of one of the data lines.

5. The display panel according to claim 3, wherein at least one branch of the at least two branches is coupled with a same position of one of the data lines.

6. The display panel according to claim 3, wherein the at least two branches are provided in a same layer and made of a same material.

7. The display panel according to claim 3, wherein the at least one first connecting line comprises a first connecting sub-line and a second connecting sub-line, wherein a number of the at least two branches of the first connecting sub-line is greater than a number of the at least two branches of the second connecting sub-line.

8. The display panel according to claim 3, wherein the at least one first connecting line comprises a third connecting sub-line and a fourth connecting sub-line, wherein a length of one branch of the at least two branches of the third connecting sub-line is different from a length of one branch of the at least two branches of the fourth connecting sub-line.

9. The display panel according to claim 2, wherein in the direction perpendicular to the plane of the substrate, the at least two branches do not overlap with the openings, and the light-shielding structure overlaps with at least one branch of the at least two branches.

10. The display panel according to claim 9, wherein one branch of the at least two branches is disposed between adjacent openings of the openings, and only at least one of line segments of the one branch of the at least two branches is arranged between the adjacent openings.

11. The display panel according to claim 10, wherein each of the at least two branches comprises a first branch segment extending in a second direction, the second direction intersecting the first direction; and
wherein, in one of the at least one first connecting line, one of the openings is arranged in a space between the first branch segment of one of the at least two branches and the first branch segment of another one of the at least two branches, wherein the one of the at least two branches and the another one of the at least two branches are adjacent to each other in the first direction.

12. The display panel according to claim 10, wherein each of the at least two branches comprises a first branch segment extending in a second direction, the second direction intersecting the first direction; and
wherein the at least one first connecting line comprises at least two first connecting lines, one of the openings is arranged in a space between the first branch segment of one of the at least two branches of one of the at least two first connecting lines and the first branch segment of one of the at least two branches of another one of the at least two first connecting lines, the one of the at least two first connecting lines is adjacent to the another one of the at least two first connecting lines, and the first branch segment of the one of the at least two branches of the one of the at least two first connecting lines is adjacent to the first branch segment of the one of the at least two branches of the another one of the at least two first connecting lines in the first direction.

13. The display panel according to claim 2, wherein each of the at least one first connecting line further comprises a main line segment, and one end of each of the at least two branches is coupled with the main line segment; and
wherein, in the direction perpendicular to the plane of the substrate, the main line segment does not overlap with the openings, and the light-shielding structure overlaps with at least a part of the main line segment.

14. The display panel according to claim 1, wherein each of at least two connecting lines of the connecting lines comprises a first line segment extending in the first direction, wherein the first line segment extends from a boundary between the display area and the non-display area to the display area; and
wherein the light-shielding structure comprises a first light-shielding portion extending in the first direction, wherein, in the direction perpendicular to the plane of the substrate, the first light-shielding portion overlaps with the first line segments of the at least two connecting lines.

15. The display panel according to claim 1, wherein the connecting lines comprise a second connecting line and a third connecting line, wherein the second connecting line has a length greater than a length of the third connecting line; and a line width of at least one of line segments of the second connecting line is greater than a line width of the third connecting line.

16. The display panel according to claim 1, wherein the display area has an axis of symmetry extending in the first direction;
wherein each of the connecting lines comprises a first line segment extending in the first direction, the first line segment extending from a boundary between the display area and the non-display area to the display area; and
wherein the connecting lines comprise a fourth connecting line and a fifth connecting line that are located at a side of the axis of symmetry, and the data lines comprise a first data line and a second data line that are located at the side of the axis of symmetry, wherein a distance between the first line segment of the fourth connecting line and the axis of symmetry is greater than a distance between the first line segment of the fifth connecting line and the axis of symmetry; a distance between the first data line and the axis of symmetry is greater than a distance between the second data line and the axis of symmetry; and the fourth connecting line is coupled with the first data line, and the fifth connecting line is coupled with the second data line.

17. The display panel according to claim 1, wherein the display area comprises a first display area and two second display areas, wherein, in a second direction, the two second display areas are respectively located at two sides of the first display area, and the second direction intersects with the first direction; the display area has an axis of symmetry extending in the first direction, the axis of symmetry being located in the first display area;
wherein the data lines comprise intermediate data lines and edge data lines, wherein the intermediate data lines are located in the first display area, and the edge data lines are located in the two second display areas; and fan-out lines are provided in the non-display area, and the intermediate data lines are coupled with the pads through the fan-out lines; and
wherein the connecting lines are located in the two second display areas, and the connecting lines are coupled with the edge data lines.

18. The display panel according to claim 1, wherein the connecting lines comprise a first line segment extending in the first direction and a second line segment extending in a second direction, the first line segment extending from a boundary between the display area and the non-display area to the display area, and the second direction intersecting with the first direction; and
wherein the second line segment has an end coupled with the first line segment and another end coupled with one of the data lines; and
wherein, in the direction perpendicular to the plane of the substrate, at least a part of the first line segment overlaps with the light-shielding structure, and at least a part of the second line segment overlaps with the light-shielding structure.

19. The display panel according to claim 2, further comprising:
a pixel definition layer having openings located in the display area,
wherein the connecting lines comprise a sixth connecting line, wherein, in the direction perpendicular to the plane of the substrate, at least one of line segments of the sixth connecting line overlaps with one of the openings.

20. The display panel according to claim 19, further comprising:
light-emitting elements located in the display area,
wherein one of the light-emitting elements corresponds to one of the openings; and the light-emitting elements comprise a red light-emitting element, a green light-emitting element and a blue light-emitting element; and
wherein, in the direction perpendicular to the plane of the substrate, at least one of the line segments of the sixth connecting line overlaps with one of the openings that corresponds to the red light-emitting element, and/or at least one of the line segments of the sixth connecting line overlaps with one of the openings that corresponds to the blue light-emitting element.

21. The display panel according to claim 1, further comprising:
a filter layer, wherein the filter layer comprises filter units, wherein a light-shielding component is provided between adjacent filter units of the filter units, and the light-shielding structure is reused as the light-shielding component.

22. A display apparatus, comprising a display panel, wherein the display panel has a display area and a non-display area; and
wherein the display panel comprises:
data lines arranged in the display area and each extending in a first direction;
connecting lines arranged in the display area;
pads arranged in the non-display area, wherein each of the connecting lines comprises one end coupled with one of the data lines, and another end coupled with one of the pads;
a substrate, wherein the data lines and the connecting lines are located at a same side of the substrate; and
a light-shielding structure located in the display area, and located at a side of the connecting lines away from the substrate, wherein, in a direction perpendicular to a plane of the substrate, the light-shielding structure overlaps with at least one of line segments of at least one of the connecting lines.
